(19) United States
(12) Patent Application Publication
(10) Pub. No.: US 2025/0072133 A1
(43) Pub. Date: Feb. 27, 2025

(54) PHOTODETECTOR AND FORMING METHOD THEREOF

(71) Applicants: Semiconductor Manufacturing International (Beijing)) Corporation, Beijing (CN); Semiconductor Manufacturing International (Shanghai) Corporation, Shanghai (CN)

(72) Inventors: Yuqing ZHANG, Beijing (CN); Xing CHEN, Beijing (CN); Zhigao WANG, Beijing (CN)

(21) Appl. No.: 18/763,730

(22) Filed: Jul. 3, 2024

(30) Foreign Application Priority Data
Aug. 22, 2023 (CN) 202311064465.9

(51) Int. Cl. H01L 27/146

(52) U.S. Cl. CPC H01L 27/14643; H01L 27/1462; H01L 27/1463; H01L 27/14685

(57) ABSTRACT

Photodetector and forming method thereof are provided. The photodetector includes a substrate including a plurality of photosensitive areas and isolation areas between adjacent photosensitive area; a diode structure in a photosensitive area of the plurality of photosensitive areas; a deep trench isolation structure in an isolation area of the isolation areas; a protruding portion at least on a top surface of the deep trench isolation structure, a surface of the protruding portion protruding relative to a surface of the substrate, and a center of the protruding portion being higher than edges of the protruding portion; and a passivation layer on surfaces of protruding portions, a refractive index of the passivation layer material being greater than a refractive index of a material of the protruding portions.

### CROSS-REFERENCE TO RELATED APPLICATION

This application claims priority of Chinese Patent Application No. 202311064465.9, filed on Aug. 22, 2023, the entire contents of which are hereby incorporated by reference.

### FIELD OF THE DISCLOSURE

The present disclosure generally relates to the field of semiconductor technology and, more particularly, relates to a photodetector and a forming method thereof.

### BACKGROUND

A silicon photomultiplier (SiPM) is a novel photodetector device with characteristics of high gain, high sensitivity, low bias voltage, insensitivity to magnetic fields, and compact structure. Upon absorbing incident photons, the SiPM triggers a photoelectric effect to detect the light signal. SiPMs are now widely applied in fields such as high-energy physics and nuclear medicine (PET), laser detection and measurement.

A SiPM is composed of a plurality of single-photon avalanche diodes (SPAD) arranged in different arrays. Each SPAD is situated within a pixel unit, and pixels units operate independently of each other. A final output signal is a superposition of output signals of a plurality of pixel units. An increase in number of photons irradiating each SPAD results in a larger signal amplitude, higher photon detection efficiency (PDE), improved optical sensitivity performance of the device, a more comprehensive acquired electrical signal, and ultimately, more detailed ranging and imaging information.

In existing technologies, each pixel unit in a SiPM is isolated from each other through a plurality of deep trench isolation structures to prevent optical crosstalk between different pixel units. However, an increasing working area occupied by the deep trench isolation structures reduces an effective photosensitive area of a device, consequently decreasing a photon detection efficiency of the device.

### BRIEF SUMMARY OF THE DISCLOSURE

One aspect of the present disclosure provides a photodetector. The photodetector includes a substrate including a plurality of photosensitive areas and isolation areas between adjacent photosensitive area; a diode structure in a photosensitive area of the plurality of photosensitive areas; a deep trench isolation structure in an isolation area of the isolation areas; a protruding portion at least on a top surface of the deep trench isolation structure, a surface of the protruding portion protruding relative to a surface of the substrate, and a center of the protruding portion being higher than edges of the protruding portion; and a passivation layer on surfaces of protruding portions, a refractive index of the passivation layer material being greater than a refractive index of a material of the protruding portions.

Another aspect of the present disclosure provides a forming method of a photodetector. The forming method includes providing a substrate including a plurality of photosensitive areas and isolation areas between adjacent photosensitive areas; forming a deep trench isolation structures between adjacent photosensitive areas; forming a diode structure in a photosensitive area of the plurality of photosensitive areas; forming a protruding portion on at least a top surface of the deep trench isolation structure, a surface of the protruding portion protruding relative to a surface of the substrate, and a center of the protruding portion being higher than edges of the protruding portion; and forming a passivation layer on surfaces of protruding portions, and a refractive index of a material of the passivation layer being greater than a refractive index of a material of the protruding portions.

Other aspects of the present disclosure can be understood by a person skilled in the art in light of the description, the claims, and accompanying drawings of the present disclosure.

### BRIEF DESCRIPTION OF THE DRAWINGS

FIGS. 1-8 illustrate cross-sectional views of a forming process of a photodetector consistent with various embodiments of the present disclosure.

FIG. 9 illustrates a flow chart of a forming method of a photodetector consistent with various embodiments of the present disclosure.

### DETAILED DESCRIPTION

As described in the background, in existing technologies, each pixel unit in a SiPM is isolated from each other through a plurality of deep trench isolation structures to prevent optical crosstalk between different pixel units. However, an increasing working area occupied by the deep trench isolation structures reduces an effective photosensitive area of a device, consequently decreasing a photon detection efficiency of the device.

To solve the above technical problem, a technical solution of the present disclosure provides a photodetector and a forming method thereof. By forming a protruding portion on a top surface of a deep trench isolation structure, a surface of the protrusion protrudes relative to a substrate surface, and a center of the protruding portion is higher than edges of the protruding portion, thereby causing a surface formed from a protruding apex to the edges of the protruding portion to be inclined relative to the substrate surface. Since a refractive index of a passivation layer is greater than a refractive index of the protruding portion, when light is incident on the top surface of the deep trench isolation structure, at least some of the photons are totally reflected on the inclined surface of the protruding portion. Using a tilt angle of the protruding portion, the photons can be reflected into the photosensitive area and captured by the diode structure, thereby increasing number of photons that each pixel unit can capture and improving a photon detection efficiency of a device.

To make the above objects, features, and beneficial effects of the present disclosure more obvious and understandable, specific embodiments of the present disclosure will be described in detail below with reference to the accompanying drawings.

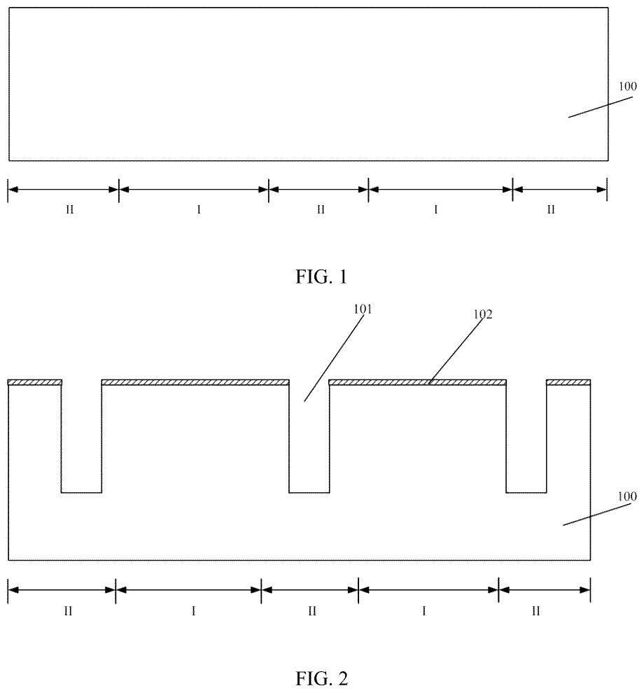

FIGS. 1-8 illustrate cross-sectional views of a forming process of a photodetector consistent with various embodiments of the present disclosure.

Referring to FIG. 1, the forming process includes providing a substrate 100 including a plurality of photosensitive areas I and isolation areas II between adjacent photosensitive areas I. A material of the substrate 100 includes silicon, silicon germanium, silicon carbide, silicon on insulator (SOI), germanium on insulator (GOI), and the like. Specifically, in one embodiment, the material of the substrate 100 is silicon.

In one embodiment, the photosensitive area I provides a platform for subsequently forming a diode structure and becomes a photon absorption area. The isolation area II provides a platform for subsequently forming a deep trench isolation structure, thereby isolating adjacent photosensitive area I to prevent optical crosstalk.

Subsequently, a deep trench isolation structure is formed between two adjacent photosensitive areas I, and a diode structure is formed in each photosensitive area I. Specific steps can be referenced in FIGS. 2-4.

Referring to FIG. 2, the forming process includes forming a first oxide layer 102 on a surface of the substrate 100; and etching the isolation area II and the first oxide layer 102 on the isolation area II to form a deep trench 101 in the isolation area II.

In one embodiment, a material of the first oxide layer 102 includes silicon oxide. The deep trench 101 provides space for a subsequently formed deep trench isolation structure.

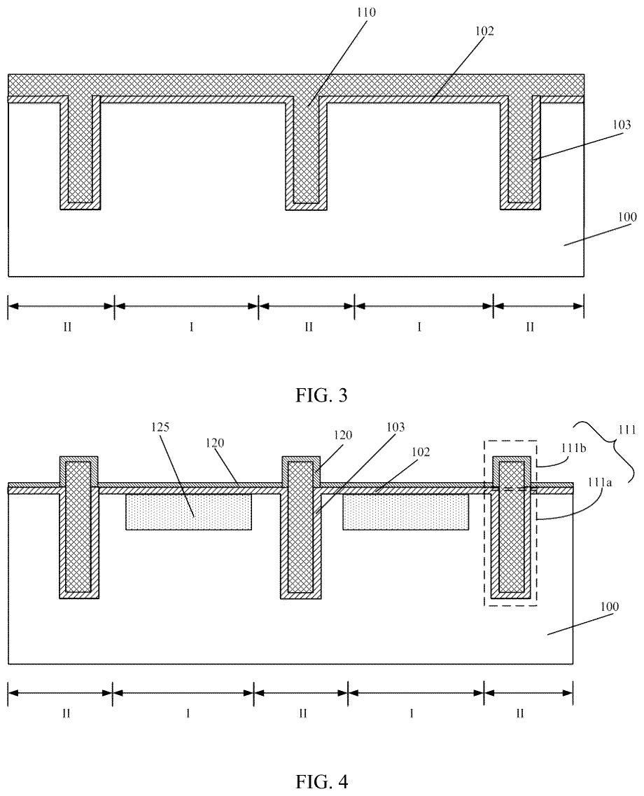

Referring to FIG. 3, the forming process includes forming a second oxide layer 103 on sidewalls and a bottom surface of the deep trench 101; and forming a deep trench isolation material layer 110 in the deep trench 101 and on a surface of the first oxide layer 102.

In one embodiment, the deep trench isolation material layer 110 provides a raw material for a subsequently formed deep trench isolation structure.

In one embodiment, a top surface of the deep trench isolation material layer 110 is higher than the surface of the first oxide layer 102.

In one embodiment, a material of the deep trench isolation material layer 110 includes oxide, polysilicon, and tungsten.

Referring to FIG. 4, the forming process includes etching the deep trench isolation material layer 110 on a surface of the photosensitive area I to form a deep trench isolation structure 111 in the deep trench 101. A top surface of the deep trench isolation structure 111 is higher than a top surface of the first oxide layer 102.

In one embodiment, the deep trench isolation structure 111 is configured to isolate photosensitive structures in adjacent photosensitive areas I to prevent optical crosstalk. The deep trench isolation structure 111 includes a first isolation portion 111a in the isolation area II and a second isolation portion 111b on a surface of the isolation area II. The second isolation portion 111b is on a surface of the first isolation portion 111a.

In another embodiment, the top surface of the deep trench isolation structure is flush with the top surface of the first oxide layer. In other embodiments, the top surface of the deep trench isolation structure is flush with the surface of the isolation area.

In one embodiment, after the deep trench isolation structure 111 is formed, a first dielectric layer 120 is formed on a top surface and a sidewall surface of the second isolation portion 111b of the deep trench isolation structure 111, and on a surface of the first oxide layer 102.

A material of the first dielectric layer 120 includes silicon oxide. In other embodiments, the first dielectric layer may also be only on sidewalls and a top surface of the second isolation portion.

In one embodiment, a diode structure 125 is formed in each photosensitive area I. The diode structure 125 is configured to absorb incident photons, thereby generating a photoelectric effect, and enabling a detection of an optical signal. In other embodiments, the diode structure may be formed before forming the deep trench isolation structure, or after forming the deep trench isolation structure and before forming the first dielectric layer.

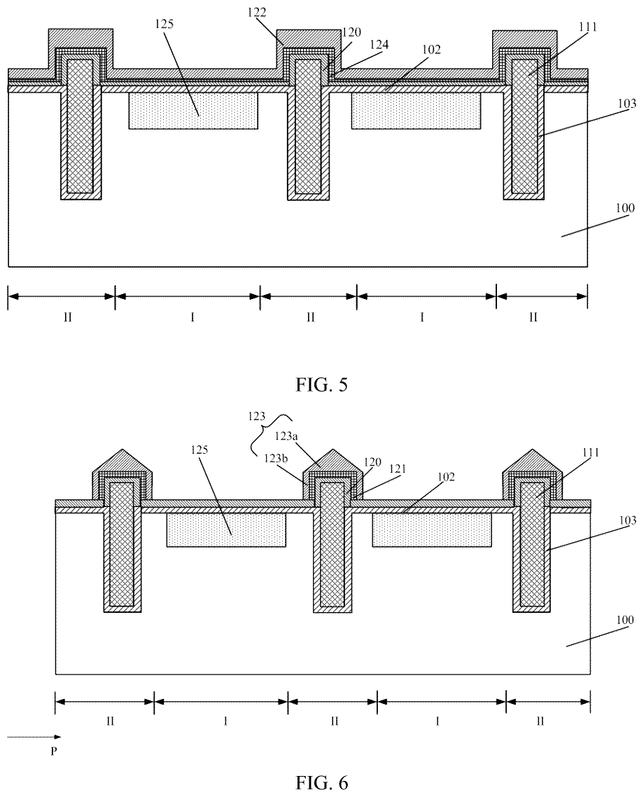

Referring to FIG. 5, the forming process includes forming an intermediate material layer 124 on a surface of the first dielectric layer 120 and forming a second material layer 122 on a surface of the intermediate material layer 124.

In one embodiment, the intermediate material layer 124 provides a raw material for subsequently forming an intermediate dielectric layer. The second material layer 122 provides a raw materials for subsequently forming a protruding portion.

Specifically, in the embodiment, the intermediate material layer 124 is on the surface of the first dielectric layer 120 on the surface of the second isolation portion 111b, and the intermediate material layer 124 is also on the surface of the first dielectric layer 120 on the surface of the photosensitive area I. The second material layer 122 is on the surface of the intermediate material layer 124 on the surface of the second isolation portion 111b, and the second material layer 122 is also on the surface of the intermediate material layer 124 on the surface of the photosensitive area I.

Referring to FIG. 6, the forming process also includes etching part of the second material layer 122 on the isolation area II to form a horizontal portion 123a on the intermediate dielectric layer 121 on the top surface of the second isolation portion 111b; removing the second material layer 122 and the intermediate material layer 124 on the surface of the photosensitive area I to form the intermediate dielectric layer 121 on the surface of the first dielectric layer 120 on the top surface and the sidewall surface of the second isolation portion 111b and a vertical portion 123b on a surface of the intermediate dielectric layer 121 on the sidewall surface of the second isolation portion 111b. The horizontal portion 123a and the vertical portion 123b together form a protruding portion 123, the surface of the protruding portion 123 protrudes relative to the surface of the substrate 100, and a center of the protruding portion 123 is higher than the edges of the protruding portion 123.

In one embodiment, the protruding portion 123 (i.e., the horizontal portion 123a) on the top surface of the deep trench isolation structure 111 has a symmetrical plane. The protruding portion 123 is axially symmetrical about a symmetrical plane. The symmetrical plane of the protruding portion 123 aligns with a symmetrical plane of the deep trench isolation structure 111. A protruding apex of the protruding portion 123 is on the symmetrical plane of the protruding portion 123.

Specifically, in the embodiment, a cross-sectional shape of the protruding portion 123 (i.e., the horizontal portion 123a) on the top surface of the deep trench isolation structure 111 along a first plane direction includes a triangle. One side of the triangle is parallel to the surface of the substrate 100, and the first plane direction is perpendicular to the surface of the substrate 100 and parallel to an arrangement direction P of each photosensitive area I.

In another embodiment, the cross-sectional shape of the protruding portion (i.e., the horizontal portion) on the top surface of the deep trench isolation structure along a first plane direction includes a trapezoid, a semicircle, or a semi-ellipse. The first plane direction is perpendicular to the surface of the substrate and parallel to the arrangement direction of each photosensitive area.

In the embodiment, the surface of the protruding portion 123 protrudes relative to the surface of the substrate 100, and the center of the protruding portion 123 is higher than the edges of the protruding portion 123, so that a surface formed from the protruding apex of the protruding portion 123 to the edges of the protruding portion 123 is inclined relative to the surface of the substrate 100. The inclined surface faces the photosensitive areas I. Therefore, when light is incident on the top surface of the deep trench isolation structure 111, using a tilt angle of the protruding portion, photons can be reflected into the photosensitive area I and captured by diode structure125, thereby increasing number of photons that each pixel unit in the photosensitive area I that can be captured.

Further, the protruding portion 123 on the top surface of the deep trench isolation structure 111 has a symmetrical plane, the protruding portion 123 is axially symmetrical about the symmetrical plane, and the symmetrical plane of the protruding portion 123 coincides with the deep trench isolation structure 111. Therefore, the top of the protruding portion 123 has two symmetrical inclined surfaces, respectively facing the two photosensitive areas I on two sides of the isolation area II where the protruding portion 123 is located. When light is incident on the top of the deep trench isolation structure 111, the two inclined surfaces can reflect photons into corresponding photosensitive areas I, so that photons are captured by the diode structure 125, thereby increasing number of photons that can be captured by a pixel unit where each photosensitive area I is located.

In the embodiment, the first dielectric layer 120 and the intermediate dielectric layer 121 on the top surface and sidewall surface of the second isolation portion 111b together form a composite dielectric layer. The protruding portions 123 are on the surface of the intermediate dielectric layer 121.

A refractive index of a material of the intermediate dielectric layer 121 is greater than a refractive index of a material of the first dielectric layer 120, and a refractive index of a material of the protruding portion 123. A composite structure including the first dielectric layer 120, the intermediate dielectric layer 121 and the protruding portion 123 on the top surface and the sidewall surface of the second isolation portion 111b can reflect or refract more photons incident on the isolation areas II to the photosensitive areas I, which are captured by the diode structure 125, thereby increasing number of photons that can be captured by the pixel unit where each photosensitive area I is located.

In the embodiment, a process of etching part of the second material layer 122 on the isolation area II to form the horizontal portion 123a on the intermediate dielectric layer 121 on the top surface of the second isolation portion 111b is an anisotropic dry etching process. Specifically, the anisotropic dry etching process includes an anisotropic reactive ion dry etching (RIE) process. In the etching process, an etching rate of the second material layer 122 in a vertical direction perpendicular to the substrate 100 is a second rate greater than a first rate, so that a top surface of the horizontal portion 123a can become an inclined surface.

Etching process parameters include an etching gas including CF4, CH2F2, CH4, O2, and Ar, and a flow rate ranging from 10 sccm˜100 sccm.

In one embodiment, the etching process used to etch part of the second material layer 122 on the isolation area II is an etching process commonly used in the sidewall process of the CMOS gate. Therefore, the process conditions are relatively mature, and the cost is low.

In one embodiment, an angle between two top edges of a triangular section of the horizontal portion 123a ranges from 0 degrees to 180 degrees. A height from a vertex to a bottom of the triangular section ranges from 1 nanometer to 3 microns. A distance between a top and a bottom of the vertical portion 123b ranges from 1 angstrom to 1000 nanometers. A thickness of the intermediate dielectric layer 121 ranges from 1 angstrom to 1000 nanometers. A height from a top to a bottom of the intermediate dielectric layer 121 ranges from 1 angstrom to 1000 nanometers. A thickness of the first dielectric layer 120 ranges from 1 angstrom to 1000 nanometers.

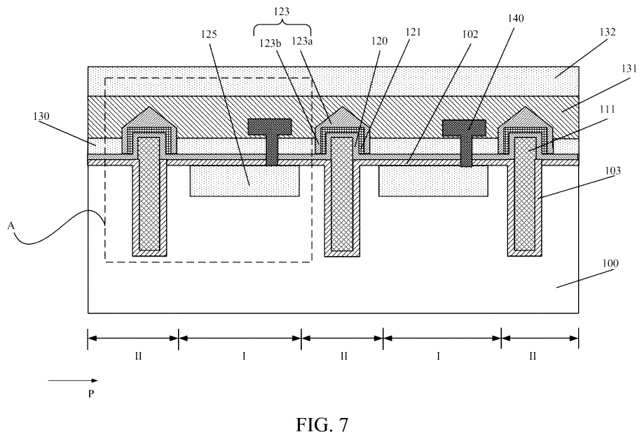

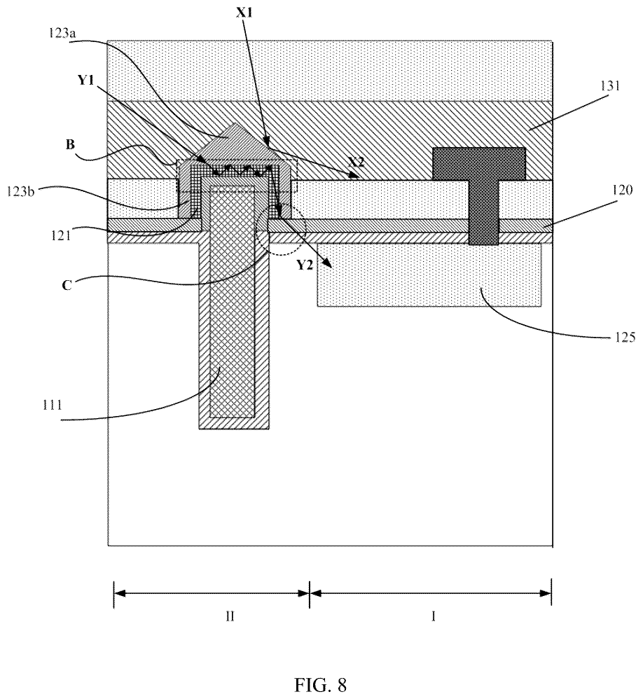

Referring to FIG. 7, the forming process further includes forming a first interlayer dielectric layer 130 on a surface of the second oxide layer 103; forming a passivation layer 131 on the first interlayer dielectric layer 130, and the passivation layer 131 being on a top surface of the protruding portion 123; and a refractive index of a material of the passivation layer 131 being greater than a refractive index of a material of the protruding portion 123.

In one embodiment, the passivation layer 131 is configured to protect the photosensitive areas I, the deep trench isolation structures 111 and the protruding portions 123.

In one embodiment, after the passivation layer 131 is formed, a second interlayer dielectric layer 132 is formed on a surface of the passivation layer 131.

In one embodiment, the refractive index of the material of the passivation layer 131 is greater than the refractive index of the material of the protruding portion 123, so that some photons are totally reflected on the inclined surface of the protruding portion 123, thereby enabling photons to be reflected into the photosensitive area I by utilizing a tilt angle of the top surface of the protruding portion 123.

In other embodiments, interlayer dielectric layers and passivation layers are alternately formed on the surface of the second oxide layer. At least one layer of the passivation layers is also on the surface of the protruding portion. A refractive index of a material of the passivation layer on the surface of the protruding portion is greater than a refractive index of a material of a material of the protruding portion.

In one embodiment, after the first interlayer dielectric layer 130 is formed, an electrical connection structure 140 is also formed in the first interlayer dielectric layer 130, and the electrical connection structure 140 and the diode structure 125 are electrically connected to each other. The passivation layer 131 surrounds the electrical connection structure 140.

Referring to FIG. 8, FIG. 8 is a partial enlarged view of area A in FIG. 7. When the photodetector is working, the diode structure 125 in the photosensitive area I is configured to capture incident light photons, thereby converting an optical signal into an electrical signal. The deep trench isolation structure 111 in isolation area II is configured to isolate adjacent photosensitive areas I to prevent optical crosstalk.

In one embodiment, a composite structure including the first dielectric layer 120, the intermediate dielectric layer 121 and the protruding portion 123 on the top surface and the sidewall surface of the second isolation portion 111b of the deep trench isolation structure 111 can reflect or refract more photons incident on the isolation area II to the photosensitive area I, thereby being captured by the diode structure 125, increasing number of photons that can be captured by the pixel unit where each photosensitive area I is located.

Specifically, there is a protruding portion 123 on the top surface of the deep trench isolation structure 111. The surface from the protruding apex to the edges of the horizontal portion 123a of the protruding portion 123 is inclined relative to the surface of the substrate 100. The inclined surface faces the photosensitive areas I. Since the refractive index of the material of the passivation layer 131 is greater than the refractive index of the material of protruding portion 123, when light is incident on the top surface of the deep trench isolation structure 111 (shown at X1), some photons whose incident angle is greater than a critical angle of total reflection can undergo total reflection on an inclined surface of the horizontal portion 123a, so that an inclination angle of the inclined surface of the horizontal portion 123a is used to enable the photons to be reflected into the photosensitive area I (shown at X2) and captured by the diode structure 125.

Since the top surface and the sidewall surface of the second isolation portion 111b of the deep trench isolation structure 111 have the first dielectric layer 120, the intermediate dielectric layer 121 on the surface of the first dielectric layer 120, and the protruding portion 123 on the surface of the intermediate dielectric layer 121, and the refractive index of the material of the intermediate dielectric layer 121 is greater than the refractive index of the material of the first dielectric layer 120 and the protruding portion 123, the first dielectric layer 120, the intermediate dielectric layer 121 and the protruding portion 123 on the second isolation portion 111b form a waveguide structure. After the photons enter the intermediate dielectric layer 121 through the passivation layer 131 and the protruding portion 123 in sequence (shown at Y1), some photons whose incident angle is greater than the critical angle of total reflection can undergo total reflection back and forth in the intermediate dielectric layer 121 on the top surface of the deep trench isolation structure 111 (shown at B) until they enter the intermediate dielectric layer 121 on the side wall of the deep trench isolation structure 111, thereby causing the incident angle to change. Therefore, the photons whose incident angle is less than the critical value can enter the vertical portion 123b from the intermediate dielectric layer 121 (shown at C) and enter the photosensitive area I and be captured by the diode structure 125 (shown at Y2), further improving the photon detection efficiency of the device.

Therefore, in the solution of the present disclosure, by disposing the protruding portion 123 with an inclined surface thereon and the waveguide structure including the first dielectric layer 120, the intermediate dielectric layer 121 and the protruding portion 123 on the surface of the second isolation portion 111b of the deep trench isolation structure 111, the deep trench isolation structure 111 that does not originally have a photosensitive function adjusts a reflection or refraction direction of the photons incident on the top surface of the deep trench isolation structure 111 and guides the photons into the photosensitive areas I to participating in photosensitivity, thereby increasing number of photons that can be captured by the pixel unit in each photosensitive area I, and improving the photon detection efficiency of the device.

In one embodiment, the material of the passivation layer 131 includes silicon nitride and the material of the protruding portion 123 includes silicon oxide. In other embodiments, the materials of passivation layer and the protruding portion may also be other materials, where the refractive index of the passivation layer is greater than the refractive index of the protruding portion. In one embodiment, the material of the first dielectric layer 120 includes silicon oxide, the material of the protrusions 123 includes silicon oxide, and the material of the intermediate dielectric layer 121 includes silicon nitride.

In other embodiments, the material of the first dielectric layer also includes silicon nitride, oxide, polysilicon, copper, aluminum, tungsten or germanium, the material of the protrusion further includes silicon nitride, oxide, polysilicon, copper, aluminum, tungsten or germanium. The material of the intermediate dielectric layer also includes silicon nitride, oxide, polysilicon, copper, aluminum, tungsten or germanium, and the material of the first dielectric layer may be same as or different from the material of the protruding portion. The materials of the first dielectric layer, the protrusions, and the intermediate dielectric layer need to satisfy that the refractive index of the intermediate dielectric layer material is greater than the refractive index of the first dielectric layer material, and the refractive index of the intermediate dielectric layer material is greater than the refractive index of the protrusion material, so that the first dielectric layer, the protruding portion, and intermediate dielectric layer constitute the waveguide structure.

In one embodiment, the top surface of the deep trench isolation structure 111 is higher than the surfaces of the isolation areas II. The deep trench isolation structure 111 includes the first isolation portion 111a in the isolation area II and the second isolation portion 111b on the surface of the isolation area II. The sidewall surface and the top surface of the second isolation portion 111b have a first dielectric layer 120, an intermediate dielectric layer 121 and a protruding portion 123.

In another embodiment, the top surface of the deep trench isolation structure is flush with the surface of the isolation area. The top surface of the deep trench isolation structure is in direct contact with the protruding portion, the surface of the protruding portion protrudes relative to the substrate surface, and the center of the protruding portion is higher than the edges of the protruding portion, Therefore, the surface formed from the protruding apex to the edges of the protruding portion is inclined relative to the surface of the substrate, and the inclined surface faces the photosensitive areas. The protruding portion is only on the top surface of the deep trench isolation structure.

Specifically, forming the protruding portion includes forming a second material layer on the surface of the substrate and the top surface of the deep trench isolation structure; etching part of the second material layer on the isolation area to form a protruding portion on the top surface of the deep trench isolation structure; and removing the second material layer on the surface of the photosensitive area.

In other embodiments, the protruding portion is also in direct contact with the top surface and the sidewall surface of the deep trench isolation structure.

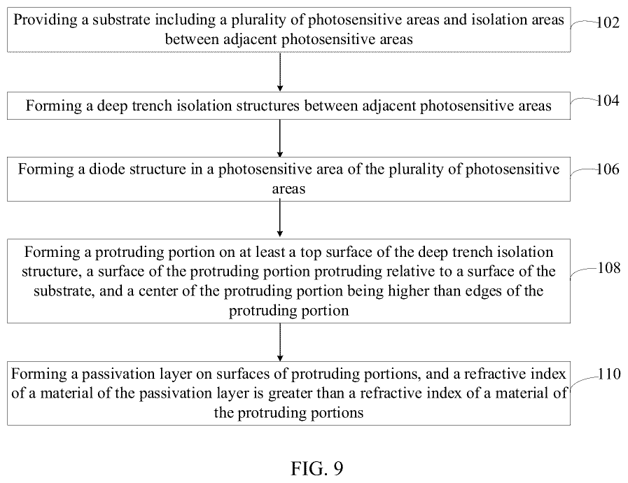

FIG. 9 illustrates a flow chart of a forming method of a photodetector consistent with various embodiments of the present disclosure. As described above, the forming method includes the following steps.

102: providing a substrate including a plurality of photosensitive areas and isolation areas between adjacent photosensitive areas.

104: forming a deep trench isolation structure between adjacent photosensitive areas.

106: forming a diode structure in a photosensitive area of the plurality of photosensitive areas.

108: forming a protruding portion on at least a top surface of the deep trench isolation structure, a surface of the protruding portion protruding relative to a surface of the substrate, and a center of the protruding portion being higher than edges of the protruding portion.

110: forming a passivation layer on surfaces of protruding portions, and a refractive index of a material of the passivation layer is greater than a refractive index of a material of the protruding portions.

Accordingly, a photodetector formed by the above method is provided in one embodiment. Referring to FIG. 7 and FIG. 8, the photodetector includes: a substrate 100, which includes a plurality of photosensitive areas I and isolation areas II between the photosensitive areas I; diode structures 125 in each photosensitive areas; deep trench isolation structures 111 in the isolation areas II; at least a protruding portion 123 on a top surface of a deep trench isolation structure 111, a surface of the protruding portion 123 protruding relative to a surface of the substrate 100, and a center of the protruding portion 123 being higher than the edge of the protruding portion 123; and a passivation layer 131 on surfaces of protruding portions 123, a refractive index of a material of the passivation layer 131 being greater than a refractive index of a material of the protruding portion 123.

A surface formed from a protruding apex to edges of the protruding portion 123 is inclined relative to a surface of the substrate 100, and the inclined surface faces the photosensitive areas I.

In one embodiment, the protruding portion 123 on the top surface of the deep trench isolation structure 111 has a symmetrical plane, the protruding portion 123 is axially symmetrical about the symmetrical plane, and the symmetrical plane of the protruding portion 123 coincides with a symmetrical plane of the deep trench isolation structure 111. The protruding apex of the protruding portion 123 is on the symmetrical plane of the protruding portion 123.

In one embodiment, a cross-sectional shape of the protruding portion 123 on the top surface of the deep trench isolation structure 111 along a first plane direction includes a triangle, one side of the triangle is parallel to the surface of the substrate 100, and the first plane direction is perpendicular to the surface of the substrate 100 and parallel to an arrangement direction P of each photosensitive area I.

In other embodiments, the cross-sectional shape of the protruding portion on the top surface of the deep trench isolation structure along a first plane direction includes a trapezoid, a semicircle, or a semi-ellipse, and the first plane direction is perpendicular to the substrate surface and parallel to the arrangement direction of each photosensitive area.

In one embodiment, a material of the passivation layer 131 includes silicon nitride and a material of the protruding portion 123 includes silicon oxide.

In one embodiment, the top surface of the deep trench isolation structure 111 is higher than surfaces of the isolation areas II. The deep trench isolation structure 111 includes a first isolation portion 111a in the isolation area II and a second isolation portion 111b on the surface of the isolation area II.

In one embodiment, the top surface of the deep trench isolation structure 111 also has a composite dielectric layer including a first dielectric layer 120 on a top surface and a sidewall surface of the second isolation portion 111b, and an intermediate dielectric layer 121 on a surface of the first dielectric layer 120. The protruding portion 123 is on a surface of the intermediate dielectric layer 121. A refractive index of a material of the intermediate dielectric layer 121 is greater than a refractive index of a material of the first dielectric layer 120, and a refractive index of the material of the protruding portion 123.

The protruding portion 123 is also on the surface of the intermediate dielectric layer 121 on a sidewall of the second isolation portion 111b.

In one embodiment, the material of the first dielectric layer 120 includes silicon oxide, the material of the protrusions 123 includes silicon oxide, and the material of the intermediate dielectric layer 121 includes silicon nitride.

In one embodiment, since the top surface of the deep trench isolation structure 111 has a protruding portion 123, the surface from the protruding apex to the edges of the protruding portion 123 is inclined relative to the surface of the substrate 100. Because the refractive index of the passivation layer 131 is greater than the refractive index of the protruding portion 123, when light is incident on the top surface of the deep trench isolation structure 111, at least some of the photons are totally reflected on the inclined surface of the protruding portion. Using a tilt angle of the protruding portion, the photons can be reflected into the photosensitive area I and captured by the diode structure 125. The photons can be reflected into the photosensitive area I and be captured by the diode structure 125 by using a tilt angle thereof. In the solution of the present disclosure, the deep trench isolation structure 111 does not originally have a photosensitive function. By arranging a protruding portion 123 on the deep trench isolation structure 111, the photons incident on the top of the deep trench isolation structure 111 can enter the photosensitive area I and participate in the photosensitivity, thereby increasing number of photons that each pixel unit can capture and improving a photon detection efficiency of the photodetector.

Furthermore, the surface of the deep trench isolation structure 111 also has a composite dielectric layer including a first dielectric layer 120 on the top and side wall surface of the second isolation portion 111b, and an intermediate dielectric layer 121 on the surface of the first dielectric layer 120. The protruding portion 123 is on the surface of the intermediate dielectric layer 121. The refractive index of the material of the intermediate dielectric layer 121 is greater than the refractive index of the material of the first dielectric layer 120, the refractive index of the material of the protruding portion 123. In the solution of the present disclosure, by disposing the protruding portion 123 with an inclined surface thereon and a waveguide structure including the first dielectric layer 120, the intermediate dielectric layer 121 and the protruding portion 123 on the surface of the second isolation portion 111b of the deep trench isolation structure 111, the deep trench isolation structure 111 that does not originally have a photosensitive function adjusts a reflection or refraction direction of the photons incident on the top of the deep trench isolation structure 111 and guides the photons into the photosensitive areas I to participate in photosensitivity, thereby increasing number of photons that can be captured by the pixel unit in each photosensitive area I, and improving the photon detection efficiency of the photodetector.

As disclosed, the photodetector and the forming method thereof provided by the present disclosure at least realize the following beneficial effects.

In the photodetector, there is a protruding portion on the top surface of the deep trench isolation structure. The center of the protruding portion is higher than the edges of the protruding portion. The surface from the apex of the protruding portion to the edge of the horizontal portion is inclined relative to the surface of the substrate. Since the refractive index of the passivation layer is greater than the refractive index of the protrusion, when the light is incident on the top of the deep trench isolation structure, at least some of the photons are totally reflected on the inclined surface of the protruding portion. Using a tilt angle of the protruding portion, the photons can be reflected into the photosensitive area and captured by the diode structure. Therefore, by disposing the protruding portion with an inclined surface thereon and a waveguide structure including the first dielectric layer, the intermediate dielectric layer and the protruding portion on the surface of the second isolation portion of the deep trench isolation structure, the deep trench isolation structure that does not originally have a photosensitive function adjusts the reflection or refraction direction of the photons incident on the top of the deep trench isolation structure and guides the photons into the photosensitive areas I to participate in photosensitivity, thereby increasing number of photons that can be captured by the pixel unit in each photosensitive area, and improving a photon detection efficiency of the photodetector.

The present disclosure is disclosed above but is not limited thereto. A person skilled in the art can make various changes and modifications without departing from the spirit and scope of the present disclosure. The scope of protection of the present disclosure shall be determined by the scope defined in the claims.

What is claimed is:

1. A photodetector, comprising:
a substrate including a plurality of photosensitive areas and isolation areas between adjacent photosensitive area;
a diode structure in a photosensitive area of the plurality of photosensitive areas;
a deep trench isolation structure in an isolation area of the isolation areas;
a protruding portion at least on a top surface of the deep trench isolation structure, a surface of the protruding portion protruding relative to a surface of the substrate, and a center of the protruding portion being higher than edges of the protruding portion; and
a passivation layer on surfaces of protruding portions, a refractive index of the passivation layer material being greater than a refractive index of a material of the protruding portions.

2. The photodetector according to claim 1, wherein the protruding portion on a top surface of the deep trench isolation structure has a symmetrical plane, the protruding portion is axially symmetrical about the symmetrical plane, and the symmetrical plane of the protrusion coincides with a symmetrical plane of the deep trench isolation structure, and a protruding apex of the protruding portion is on the symmetrical plane of the protruding portion.

3. The photodetector according to claim 2, wherein a cross-sectional shape of the of the protruding portion on the top surface of the deep trench isolation structure along a first plane direction includes a triangle, one side of the triangle is parallel to the surface of the substrate, and the first plane direction is perpendicular to the surface of the substrate and parallel to an arrangement direction of each photosensitive area.

4. The photodetector according to claim 2, wherein the cross-sectional shape of the of the protruding portion on the top surface of the deep trench isolation structure along a first plane direction includes a trapezoid, a semicircle, or a semi-ellipse, and the first plane direction is perpendicular to the surface of the substrate and parallel to an arrangement direction of each photosensitive area.

5. The photodetector according to claim 1, wherein a material of the passivation layer includes silicon nitride, and a material of the protruding portions includes silicon oxide.

6. The photodetector according to claim 1, wherein a top surface of the deep trench isolation structure is flush with a surface of an isolation area.

7. The photodetector according to claim 1, wherein a top surface of the deep trench isolation structure is higher than a surface of the isolation area, the deep trench isolation structure includes a first isolation portion in an isolation area and a second isolation portion on a surface of the isolation area.

8. The photodetector according to claim 7, wherein a surface of the deep trench isolation structure also has a composite dielectric layer including a first dielectric layer on a top surface and a sidewall surface of the second isolation portion, and an intermediate dielectric layer on a surface of the first dielectric layer, the protruding portion is on a surface of the intermediate dielectric layer, a refractive index of a material of the intermediate dielectric layer is greater than a refractive index of a material of the first dielectric layer material, and a refractive index of a material of the protruding portion.

9. The photodetector according to claim 8, wherein the protruding portion is also on the surface of the intermediate dielectric layer of a sidewall of the second isolation portion.

10. The photodetector according to claim 8, wherein a material of the first dielectric layer includes silicon oxide, a material of the protruding portion includes silicon oxide, and a material of the intermediate dielectric layer includes silicon nitride.

11. A method of forming a photodetector, comprising:
providing a substrate including a plurality of photosensitive areas and isolation areas between adjacent photosensitive areas;
forming a deep trench isolation structure between adjacent photosensitive areas;
forming a diode structure in a photosensitive area of the plurality of photosensitive areas:
forming a protruding portion on at least a top surface of the deep trench isolation structure, a surface of the protruding portion protruding relative to a surface of the substrate, and a center of the protruding portion being higher than edges of the protruding portion; and
forming a passivation layer on surfaces of protruding portions, and a refractive index of a material of the passivation layer being greater than a refractive index of a material of the protruding portions.

12. The method according to claim 11, wherein the top surface of the deep trench isolation structure is higher than a surface of an isolation area, the deep trench isolation structure includes a first isolation portion in an isolation area and a second isolation portion on the surface of the isolation area.

13. The method according to claim 12, wherein a composite dielectric layer is formed on a surface of the deep trench isolation structure, the composite dielectric layer includes a first dielectric layer on a top surface and a sidewall surface of the second isolation portion, and an intermediate dielectric layer on a surface of the first dielectric layer on the top surface and the sidewall surface of the second isolation portion, the protruding portion is on a surface of the intermediate dielectric layer, a refractive index of a material of the intermediate dielectric layer is greater than a refractive index of a material of the first dielectric layer, and a refractive index of a material of the protruding portion.

14. The method according to claim 13, wherein forming the composite dielectric layer and the protruding portion includes: forming a first dielectric layer on the surface of the substrate, the top surface and the sidewall surface of the second isolation portion; forming an intermediate material layer on the surface of the first dielectric layer; forming a second material layer on a surface of the intermediate material layer; etching part of the second material layer on the isolation area to form a horizontal portion on the intermediate dielectric layer on the top surface of the second isolation portion; and removing the second material layer and the intermediate material layer on a surface of the photosensitive area, and forming an intermediate dielectric layer on the surface of the first dielectric layer on the top surface and the sidewall surface of the second isolation portion and a vertical portion on the surface of the intermediate dielectric layer on the sidewall surface of the second isolation portion, the horizontal portion and the vertical portion forming a protruding portion.

15. The method according to claim 11, wherein the top surface of the deep trench isolation structure is flush with surfaces of the isolation areas.

16. The method according to claim 15, wherein forming the protruding portion includes:
forming a second material layer on the surface of the substrate and the top surface of the deep trench isolation structure;
etching part of the second material layer on the isolation area to form a protruding portion on the top surface of the deep trench isolation structure; and
removing the second material layer on a surface of the photosensitive area.

17. The method according to claim 13, wherein the protruding portion is also on the surface of the intermediate dielectric layer of a sidewall of the second isolation portion.

18. The method according to claim 13, wherein a material of the first dielectric layer includes silicon oxide, a material of the protruding portion includes silicon oxide, and a material of the intermediate dielectric layer includes silicon nitride.
